(19) United States
(12) Patent Application Publication
(10) Pub. No.: US 2006/0169209 A1
(43) Pub. Date: Aug. 3, 2006

(54) Substrate processing apparatus, substrate processing method, and storage medium storing program for implementing the method

(75) Inventor: Shinichi Miyano, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTON LIMITED, Minato-ku (JP)

(21) Appl. No.: 11/342,613

(22) Filed: Jan. 31, 2006

Related U.S. Application Data
(60) Provisional application No. 60/653,099, filed on Feb. 16, 2005.

(30) Foreign Application Priority Data
Feb. 1, 2005 (JP) 2005-025271

(51) Int. Cl. H01L 21/336; C23C 16/00

(52) U.S. Cl. 118/719; 438/300

(57) ABSTRACT

A substrate processing apparatus that enables a plurality of substrates to be subjected to stable plasma processing. A chamber 11 houses a wafer W. The wafer W is subjected to reactive ion etching in the chamber 11. A focus ring 25 has p-type silicon as a parent material thereof. At least part of the focus ring 25 is exposed to an interior of the chamber 11. The focus ring 25 has been subjected to heat treatment at least once.

### BACKGROUND OF THE INVENTION

1. Field of the Invention

The present invention relates to a substrate processing apparatus, a substrate processing method, and a storage medium storing a program for implementing the method, and in particular relates to a substrate processing apparatus having a component element having p-type silicon as a parent material thereof disposed in a processing chamber in which a plasma is produced.

2. Description of the Related Art

Generally, a substrate processing apparatus that carries out predetermined plasma processing on substrates such as semiconductor device wafers has a processing chamber (hereinafter referred to as the “chamber”) in which a substrate is housed and subjected to the predetermined plasma processing. In such a substrate processing apparatus, a processing gas is introduced into the chamber, and a high-frequency electric field is generated in the chamber, whereby the processing gas is made into a plasma and hence ions and radicals are produced, the substrate being subjected to the plasma processing by the ions and radicals.

Moreover, a focus ring made of silicon is disposed surrounding the substrate in the chamber. The focus ring focuses the produced ions and radicals toward a surface of the substrate, thus improving the efficiency of the plasma processing (see, for example, Japanese Laid-open Patent Publication (Kokai) No. 2000-82699). The focus ring is repeatedly exposed to a high-temperature plasma atmosphere in the chamber during plasma processing of a large number of (i.e. a plurality of lots of) substrates.

In recent years, wafers having p-type silicon as a parent material thereof have come to be widely used as semiconductor device wafers, and hence p-type silicon is generally used as a focus ring material. P-type silicon is electrically conductive due to positive holes due to boron (B), which is a group 13 element, added to the silicon, which is a semiconductor when pure. However, if a focus ring having p-type silicon as a parent material thereof is repeatedly exposed to a plasma atmosphere, then oxygen atoms that get into the p-type silicon as an impurity upon heating bond to the silicon atoms, whereby a silicon oxide (SiO₄) is formed in the p-type silicon. This SiO₄ supplies free electrons into the p-type silicon, and the positive holes electrically constrain the supplied free electrons. During repeated exposure of the focus ring to the plasma atmosphere, SiO₄ continues to be formed, and hence free electrons continue to be supplied. Eventually, the number of free electrons supplied exceeds the number of positive holes, and hence the focus ring comes to be apparently made of n-type silicon (p-n inversion).

If the focus ring undergoes such p-n inversion during plasma processing on a plurality of lots of substrates, then the specific resistance value of the focus ring becomes unstable, changing as the plasma processing is repeated. Specifically, the focus ring is initially electrically conductive (i.e. has a low specific resistance value) due to the number of positive holes exceeding the number of free electrons, but during the repeated plasma processing, the specific resistance value increases as electrical constraint of free electrons by positive holes proceeds, and then eventually the number of free electrons becomes greater than the number of positive holes, whereupon the specific resistance value once again decreases.

There is a problem that if the specific resistance value of the focus ring changes during plasma processing on a plurality of lots of substrates as described above, then the distribution of the high-frequency electric field around the substrate changes, and hence stable plasma processing cannot be carried out on the plurality of lots of substrates. In particular, in recent years, the dimension to which wiring and electrodes in semiconductor devices manufactured from substrates are required to be fabricated has become smaller, and hence the plasma atmosphere in the chamber, and thus the high-frequency electric field, is now required to be even more stable than in the past, resulting in the above problem becoming more prominent.

### SUMMARY OF THE INVENTION

It is an object of the present invention to provide a substrate processing apparatus, a substrate processing method, and a storage medium storing a program for implementing the method that enable a plurality of substrates to be subjected to stable plasma processing.

To attain the above object, in a first aspect of the present invention, there is provided a substrate processing apparatus comprising a processing chamber in which a substrate is housed and subjected to plasma processing, and a component element having p-type silicon as a parent material thereof, at least part of the component element being exposed to an interior of the processing chamber, wherein the component element has been subjected to heat treatment at least once.

According to the construction of the first aspect as described above, the component element that has p-type silicon as a parent material thereof and has at least part thereof exposed to the interior of the processing chamber in which a substrate is subjected to plasma processing is subjected to heat treatment at least once. Upon the p-type silicon being subjected to the heat treatment, formation of a silicon oxide from oxygen atoms present as an impurity and silicon atoms is promoted, whereby free electrons are supplied into the p-type silicon, and hence the number of free electrons becomes greater than the number of positive holes in the component element, and thus the p-type silicon is inverted into apparently n-type silicon; after that, the formation of silicon oxide levels off, and hence the supply of free electrons into the p-type silicon stops. As a result, during subsequent repeated plasma processing, the specific resistance value of the component element does not change. A plurality of substrates can thus be subjected to stable plasma processing.

Preferably, the component element has regions therein where a density of interstitial oxygen atoms is lower than an overall density of oxygen atoms in a silicon crystal lattice.

According to the construction of the first aspect as described above, the component element has regions therein where the density of interstitial oxygen atoms is lower than the overall density of oxygen atoms in the silicon crystal lattice. Such a case that the density of interstitial oxygen atoms in specific regions of the silicon crystal lattice is lower than the overall density of oxygen atoms corresponds to some of the interstitial oxygen atoms in the specific regions being bonded to silicon atoms. Due to oxygen atoms being bonded to silicon atoms, donors that supply free electrons are formed, and hence the number of free electrons in the component element after the heat treatment can be made to exceed the number of positive holes reliably. The specific resistance value of the component element can thus be made stable, and hence a plurality of substrates can be subjected to yet more stable plasma processing.

Preferably, the p-type silicon is formed by adding a group 13 element to silicon, and in the component element, a number density of donors formed through bonding between interstitial atoms and silicon atoms in a silicon crystal lattice of the component element is higher than a number density of acceptors comprising the group 13 element in the silicon crystal lattice.

According to the construction of the first aspect as described above, the p-type silicon is formed by adding a group 13 element to silicon, and in the component element, the number density of donors formed through bonding between interstitial atoms and silicon atoms in the silicon crystal lattice of the component element is higher than the number density of acceptors comprising the group 13 element in the silicon crystal lattice. Each acceptor comprising an atom of the group 13 element produces one positive hole, and hence if the number density of the donors is higher than the number density of the acceptors comprising the group 13 element, then the number of free electrons in the component element after the heat treatment can be made to exceed the number of positive holes reliably. The specific resistance value of the component element can thus be made stable, and hence a plurality of substrates can be subjected to yet more stable plasma processing.

More preferably, the interstitial atoms are oxygen atoms, and the number density of the oxygen atoms bonded to silicon atoms is not less than one half of the number density of the acceptors comprising the group 13 element.

According to the construction of the first aspect as described above, the interstitial atoms are oxygen atoms, and the number density of the oxygen atoms bonded to silicon atoms is not less than one half of the number density of the acceptors comprising the group 13 element. The oxygen atoms bonded to silicon atoms act as bivalent donors, and hence if the number density of these oxygen atoms is not less than one half of the number density of the acceptors comprising the group 13 element, then the number of free electrons in the component element after the heat treatment can be made to exceed the number of positive holes reliably.

Preferably, the component element is a focus ring provided surrounding the substrate housed in the processing chamber.

According to the construction of the first aspect as described above, the component element subjected to heat treatment at least once is a focus ring provided surrounding the substrate housed in the processing chamber. As a result, a high-frequency electric field around the substrate in the processing chamber can be made stable, and hence a plurality of substrates can be subjected to stable plasma processing reliably.

Alternatively, preferably, the component element is an upper electrode disposed in an upper portion of the processing chamber.

According to the construction of the first aspect as described above, the component element subjected to heat treatment at least once is an upper electrode disposed in an upper portion of the processing chamber. As a result, a high-frequency electric field above the substrate in the processing chamber can be made stable, and hence a plurality of substrates can be subjected to stable plasma processing reliably.

To attain the above object, in a second aspect of the present invention, there is provided a substrate processing apparatus comprising a processing chamber in which a substrate is housed and subjected to plasma processing, and a component element having p-type silicon as a parent material thereof, at least part of the component element being exposed to an interior of the processing chamber, wherein a predetermined amount of a group 13 element is added to the p-type silicon, and wherein a specific resistance value of the component element is lower than a specific resistance value of the p-type silicon to which the predetermined amount of the group 13 element has been added.

According to the construction of the second aspect as described above, a predetermined amount of a group 13 element is added to the p-type silicon, and the specific resistance value of the component element that has the p-type silicon as a parent material thereof and has at least part thereof exposed to the interior of the processing chamber is lower than the specific resistance value of the p-type silicon to which the predetermined amount of the group 13 element has been added. Because the specific resistance value of the component element is lower than the specific resistance value of the p-type silicon to which the predetermined amount of the group 13 element has been added, in the component element, formation of a silicon oxide from oxygen atoms present as an impurity and silicon atoms is promoted, and hence the number of free electrons becomes greater than the number of positive holes, and thus the p-type silicon is inverted into apparently n-type silicon. As a result, change of the specific resistance value of the component element during subsequent repeated plasma processing can be suppressed, and hence a plurality of substrates can be subjected to stable plasma processing.

To attain the above object, in a third aspect of the present invention, there is provided a substrate processing method of subjecting a substrate to plasma processing, the method comprising a housing step of housing a substrate in a processing chamber in which is disposed a component element that has p-type silicon as a parent material thereof and has been subjected to heat treatment at least once, and a plasma processing step of subjecting the substrate to plasma processing with a plasma produced in the processing chamber.

According to the construction of the third aspect as described above, a substrate is housed in a processing chamber in which is disposed a component element that has p-type silicon as a parent material thereof and has been subjected to heat treatment at least once, and the substrate is subjected to plasma processing with a plasma produced in the processing chamber. Upon the p-type silicon being subjected to the heat treatment, formation of a silicon oxide from oxygen atoms present as an impurity and silicon atoms is promoted, whereby free electrons are supplied into the p-type silicon, and hence the number of free electrons becomes greater than the number of positive holes in the component element, and thus the p-type silicon is inverted into apparently n-type silicon; after that, the formation of silicon oxide levels off, and hence the supply of free electrons into the p-type silicon stops. As a result, during subsequent repeated plasma processing in the processing chamber, the specific resistance value of the component element does not change. A plurality of substrates can thus be subjected to stable plasma processing.

To attain the above object, in a fourth aspect of the present invention, there is provided a computer-readable storage medium storing a program for causing a computer to implement a substrate processing method of subjecting a substrate to plasma processing, the program comprising a housing module for housing a substrate in a processing chamber in which is disposed a component element that has p-type silicon as a parent material thereof and has been subjected to heat treatment at least once, and a plasma processing module for subjecting the substrate to plasma processing with a plasma produced in the processing chamber.

The above and other objects, features, and advantages of the invention will become more apparent from the following detailed description taken in conjunction with the accompanying drawings.

### BRIEF DESCRIPTION OF THE DRAWINGS

FIG. 1 is a sectional view schematically showing the construction of a substrate processing apparatus according to an embodiment of the present invention;

FIG. 2 is a flowchart showing a method of manufacturing a focus ring appearing in FIG. 1;

FIGS. 3A to 3C are drawings showing the distribution of positive holes and free electrons in the focus ring appearing in FIG. 1; specifically:

FIG. 3A is a drawing showing the distribution when heat treatment is commenced;

FIG. 3B is a drawing showing the distribution during the heat treatment; and

FIG. 3C is a drawing showing the distribution after the heat treatment; and

FIG. 4 is a graph showing the relationship between the heat treatment time and a specific resistance value of the focus ring.

### DETAILED DESCRIPTION OF THE PREFERRED EMBODIMENTS

The present invention will now be described in detail with reference to the drawings showing preferred embodiments thereof.

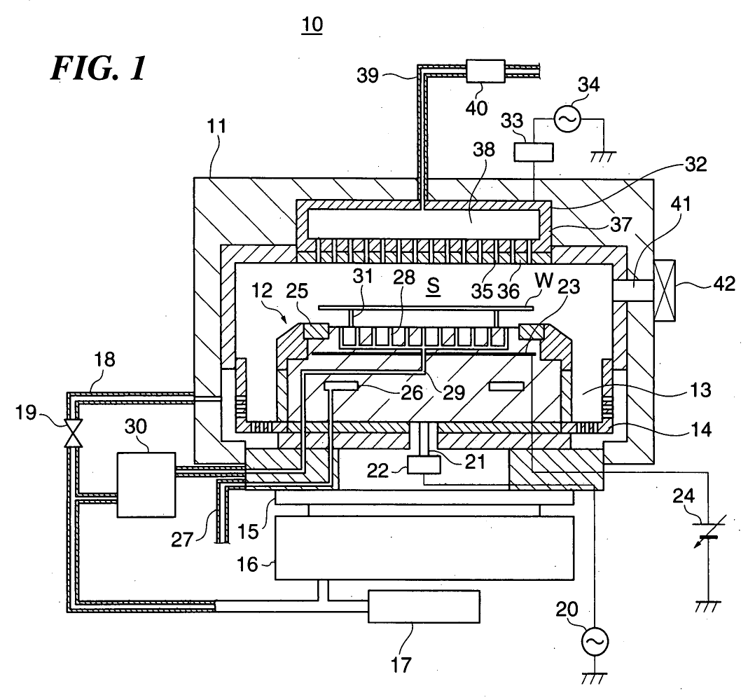

FIG. 1 is a sectional view schematically showing the construction of a substrate processing apparatus according to an embodiment of the present invention.

As shown in FIG. 1, the substrate processing apparatus 10, which subjects semiconductor device wafers (hereinafter referred to merely as “wafers”) W to dry etching (reactive ion etching) (hereinafter referred to as “RIE”) as desired plasma processing, has a cylindrical chamber 11 made of a metal such as aluminum or stainless steel. A cylindrical susceptor 12 is disposed in the chamber 11 as a stage on which is mounted a wafer W having a diameter of, for example, 300 mm.

In the substrate processing apparatus 10, an exhaust path 13 that acts as a flow path through which gas molecules above the susceptor 12 are exhausted to the outside of the chamber 11 is formed between a side wall of the chamber 11 and a side face of the susceptor 12. An annular baffle plate (exhaust plate) 14 that prevents exhausted gas molecules from flowing back into the chamber 11 is disposed part way along the exhaust path 13. A space in the exhaust path 13 downstream of the baffle plate 14 bends round below the susceptor 12, and is communicated with an automatic pressure control valve (hereinafter referred to as the “APC valve”) 15, which is a variable butterfly valve. The APC valve 15 is connected to a turbo-molecular pump (hereinafter referred to as the “TMP”) 16, which is an exhausting pump for evacuation, and via the TMP 16, to a dry pump (hereinafter referred to as the “DP”) 17, which is also an exhausting pump. The exhaust flow path comprised by the APC valve 15, the TMP 16 and the DP 17 is hereinafter referred to as the “main exhaust line”. The main exhaust line is used for controlling the pressure in the chamber 11 using the APC valve 15, and also for reducing the pressure in the chamber 11 down to a substantially vacuum state using the TMP 16 and the DP 17.

The space in the exhaust path 13 downstream of the baffle plate 14 is also connected to another exhaust flow path (roughing line) separate to the main exhaust line. The roughing line is comprised of an exhaust pipe 18 having a diameter of, for example, 25 mm that communicates the above space with the DP 17, and a valve 19 disposed part way along the exhaust pipe 18. The valve 19 is able to shut off the above space from the DP 17. The roughing line is used for exhausting gas in the chamber 11 using the DP 17.

A lower electrode high-frequency power source 20 is connected to the susceptor 12 via a feeder rod 21 and a matcher 22. The lower electrode high-frequency power source 20 supplies predetermined high-frequency electrical power to the susceptor 12. The susceptor 12 thus acts as a lower electrode. The matcher 22 reduces reflection of the high-frequency electrical power from the susceptor 12 so as to maximize the efficiency of the supply of the high-frequency electrical power into the susceptor 12.

A disk-shaped electrode plate 23 comprised of an electrically conductive film is provided in an upper portion of the susceptor 12. A DC power source 24 is electrically connected to the electrode plate 23. A wafer W is attracted to and held on an upper surface of the susceptor 12 through a Johnsen-Rahbek force or a Coulomb force generated by a DC voltage applied to the electrode plate 23 from the DC power source 24. Moreover, an annular focus ring 25 (component element) manufactured using a method of manufacturing the focus ring, described below, is provided on the susceptor 12 so as to surround the wafer W attracted to and held on the upper surface of the susceptor 12. The focus ring 25 is exposed to a space S, described below, and focuses ions and radicals produced in the space S toward a surface of the wafer W, thus improving the efficiency of the RIE.

An annular coolant chamber 26 that extends, for example, in a circumferential direction of the susceptor 12 is provided inside the susceptor 12. A coolant, for example cooling water, at a predetermined temperature is circulated through the coolant chamber 26 via coolant piping 27 from a chiller unit (not shown). A processing temperature of the wafer W attracted to and held on the upper surface of the susceptor 12 is controlled through the temperature of the coolant.

A plurality of heat-transmitting gas supply holes 28, and heat-transmitting gas supply channels (not shown), are provided in a portion of the upper surface of the susceptor 12 on which the wafer W is attracted and held (hereinafter referred to as the “attracting surface”). The heat-transmitting gas supply holes 28 are connected to a heat-transmitting gas supply unit 30 by a heat-transmitting gas supply line 29 provided inside the susceptor 12. The heat-transmitting gas supply unit 30 supplies a heat-transmitting gas, for example He gas, into a gap between the attracting surface of the susceptor 12 and a rear surface of the wafer W. Moreover, the heat-transmitting gas supply unit 30 is connected to the exhaust pipe 18, and is thus constructed so as to also be able to evacuate the gap between the attracting surface of the susceptor 12 and the rear surface of the wafer W using the DP 17.

A plurality of pusher pins 31 are provided in the attracting surface of the susceptor 12 as lifting pins that can be made to project out from the upper surface of the susceptor 12. The pusher pins 31 are connected to a motor (not shown) by a ball screw (not shown), and can thus be moved in an up/down direction in FIG. 1 through rotational motion of the motor, which is converted into linear motion by the ball screw. The pusher pins 31 are housed inside the susceptor 12 when a wafer W is being attracted to and held on the attracting surface of the susceptor 12 so that the wafer W can be subjected to the RIE, and are made to project out from the upper surface of the susceptor 12 so as to lift the wafer W up away from the susceptor 12 when the wafer W is to be transferred out from the chamber 11 after having been subjected to the RIE.

A shower head 32 is disposed in a ceiling portion of the chamber 11 facing the susceptor 12. An upper electrode high-frequency power source 34 is connected to the shower head 32 via a matcher 33. The upper electrode high-frequency power source 34 supplies predetermined high-frequency electrical power to the shower head 32. The shower head 32 thus acts as an upper electrode. The matcher 33 has a similar function to the matcher 22, described earlier.

The shower head 32 is comprised of an electrode plate 36 on a lower surface thereof, the electrode plate 36 having therein a large number of gas-passing holes 35, and an electrode support 37 on which the electrode plate 36 is detachably supported. Here, because wafers W made of p-type silicon are subjected to RIE in the substrate processing apparatus 10, p-type silicon is generally used as a material of the electrode plate 36. A buffer chamber 38 is provided inside the electrode support 37. A processing gas introducing pipe 39 is connected from a processing gas supply unit (not shown) to the buffer chamber 38. A piping insulator 40 is disposed part way along the processing gas introducing pipe 39. The piping insulator 40 is made of an electrically insulating material, and prevents the high-frequency electrical power supplied to the shower head 32 from leaking into the processing gas supply unit via the processing gas introducing pipe 39. A processing gas supplied from the processing gas introducing pipe 39 into the buffer chamber 38 is supplied by the shower head 32 into the chamber 11 via the gas-passing holes 35.

A transfer port 41 for the wafers W is provided in a side wall of the chamber 11 in a position at the height of a wafer W that has been lifted up from the susceptor 12 by the pusher pins 31. A gate valve 42 for opening and closing the transfer port 41 is provided in the transfer port 41.

Upon supplying high-frequency electrical power to the susceptor 12 and the shower head 32 in the chamber 11 of the substrate processing apparatus 10 as described above, and thus applying high-frequency electrical power into the space S between the susceptor 12 and the shower head 32, a high-density plasma is produced from the processing gas supplied into the space S from the shower head 32, and the wafer W is subjected to the RIE by the plasma.

Specifically, when subjecting a wafer W to the RIE in the substrate processing apparatus 10, first the gate valve 42 is opened, and the wafer W to be processed is transferred into the chamber 11, and attracted to and held on the attracting surface of the susceptor 12 by applying a DC voltage to the electrode plate 23. A processing gas (e.g. a mixed gas comprised of C₄F₈ gas, O₂ gas and Ar gas with a predetermined flow rate ratio therebetween) is supplied into the chamber 11 at a predetermined flow rate, and the pressure inside the chamber 11 is set to a predetermined value using the APC valve 15 and so on. Furthermore, high-frequency electrical power is supplied to the susceptor 12 and the shower head 32, and thus applied into the space S in the chamber 11. The processing gas introduced in from the shower head 32 is thus made into a plasma, whereby ions and radicals are produced in the space S. The produced ions and radicals are focused onto the surface of the wafer W by the focus ring 25, whereby the surface of the wafer W is physically/chemically etched.

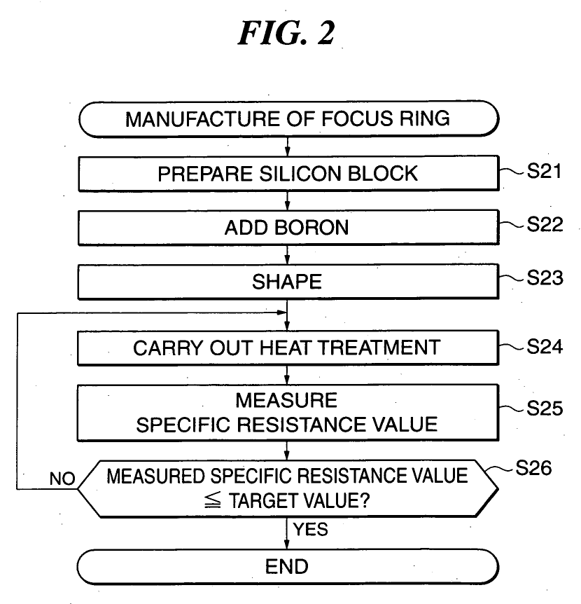

FIG. 2 is a flowchart showing a method of manufacturing the focus ring appearing in FIG. 1.

As shown in FIG. 2, first, a silicon block of predetermined size made of silicon containing a small amount of oxygen atoms as an impurity is prepared (step S21). In the silicon block, the oxygen atoms are in the form of interstitial oxygen atoms present at interstitial sites in the silicon crystal lattice.

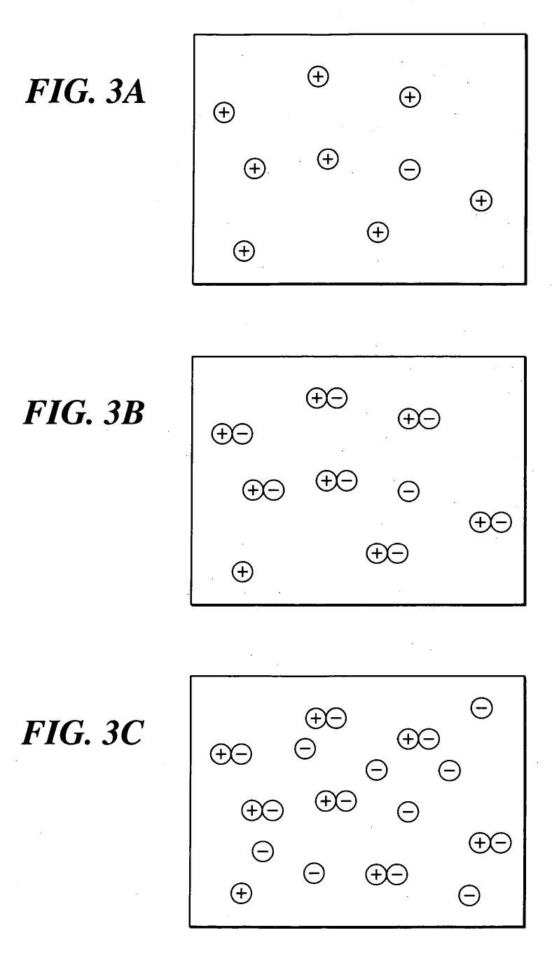

Next, a predetermined amount of a group 13 element, for example boron, is added to the silicon block (step S22). In the silicon block to which the boron has been added, some of the silicon atoms in the silicon crystal lattice are replaced by boron atoms. The some of silicon atoms and the boron atoms are electrically bonded together by electrons. However, because boron has one fewer valence electron than silicon, the boron atoms act as acceptors producing positive holes, with one positive hole per boron atom being produced between the silicon atoms and the boron atoms. As a result, the number of positive holes becomes greater than the number of free electrons in the silicon block as shown in FIG. 3A. Positive holes not electrically constraining a free electron thus act as carriers of positive charge, whereby the constituent material of the silicon block is altered into p-type silicon, and thus becomes electrically conductive.

Next, the silicon block made of p-type silicon is shaped into the annular focus ring 25 by machining (step S23), and then the shaped focus ring 25 is subjected to heat treatment (annealing) at least once by being heated to a predetermined temperature for a predetermined time (step S24).

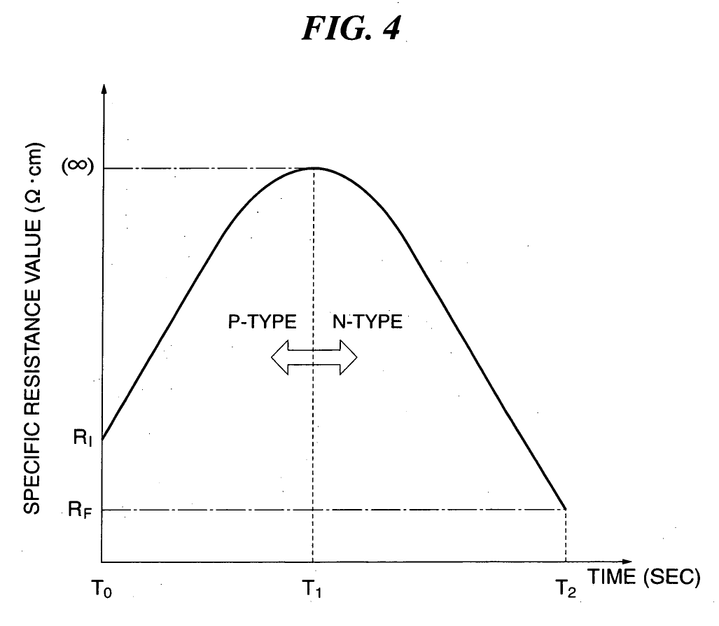

FIG. 4 is a graph showing the relationship between the heat treatment time and a specific resistance value of the focus ring. In the graph of FIG. 4, the axis of abscissas shows the heat treatment time, and the axis of ordinates shows the specific resistance value.

As shown in FIG. 4, at a heat treatment commencement time T₀, because the number of positive holes exceeds the number of free electrons in the focus ring 25 as described above, the focus ring 25 is electrically conductive, and thus has a relatively low specific resistance value of R_{I} Ω·cm.

After that, as the heat treatment time elapses, oxygen atoms contained as an impurity in the focus ring 25 bond to silicon atoms in the focus ring 25, whereby a silicon oxide (SiO₄) is formed in the p-type silicon crystal lattice. At this time, in the silicon crystal lattice, some of the silicon atoms are changed into SiO₄, and the SiO₄ is electrically bonded to silicon atoms by electrons. Oxygen atoms that bond to silicon atoms in the formation of the SiO₄ are bivalent, and hence each oxygen atom acts as a bivalent donor, whereby the SiO₄ also acts as a donor, supplying free electrons into the silicon crystal lattice, i.e. the focus ring 25. The positive holes electrically constrain the supplied free electrons, whereby the specific resistance value of the focus ring 25 increases.

As the heat treatment continues, SiO₄ continues to be formed, and hence free electrons continue to be supplied. Eventually, the numbers of positive holes and free electrons in the focus ring 25 become equal at a heat treatment time T₁ (FIG. 3B). At this time, the positive holes and the free electrons constrain one another, and hence the focus ring 25 becomes electrically non-conductive, and in theory the specific resistance value of the focus ring 25 becomes infinite (∞).

Then, upon the heat treatment being further continued, SiO₄ continues to be formed, and hence free electrons continue to be supplied into the focus ring 25. Once a predetermined heat treatment time T₂ has elapsed, the formation of SiO₄ levels off, whereby the supply of free electrons into the focus ring 25 stops. At this time, the number of free electrons exceeds the number of positive holes in the focus ring 25 (FIG. 3C), and hence free electrons not electrically constrained by positive holes act as carriers of negative charge, whereby the constituent material of the silicon block is altered into apparently n-type silicon. As a result, the specific resistance value of the focus ring 25 decreases, finally becoming, for example, a value R_{F} Q·cm that is lower than the specific resistance value R_{I} Q·cm at the heat treatment commencement time T₀. That is, upon carrying out the heat treatment on the focus ring 25 having as a parent material p-type silicon to which a predetermined amount of boron has been added, the specific resistance value of the focus ring 25 once the formation of SiO₄ has leveled off (i.e. the specific resistance value after the predetermined heat treatment time T₂ has elapsed) is lower than the specific resistance value of the p-type silicon to which the predetermined amount of boron has been added but heat treatment has not been carried out (the specific resistance value at the heat treatment commencement time T₀).

In the heat treatment described above, interstitial oxygen atoms are used in the formation of SiO₄ with silicon atoms, and hence in the focus ring 25 after the predetermined heat treatment time T₂ has elapsed, the number of interstitial oxygen atoms is reduced. Specific regions where the density of interstitial oxygen atoms is lower than the overall density of oxygen atoms including both oxygen atoms bonded to silicon atoms and interstitial oxygen atoms not bonded to silicon atoms thus arise in the silicon crystal lattice. Here, the density of the interstitial oxygen atoms, i.e. the interstitial oxygen atom concentration, can be measured using a known measurement method, for example a measurement method using infrared absorption (see, for example, http://it.jeita.or.jp/eltech/report/2000/00-ki-15.html).

Moreover, because the formation of SiO₄ is promoted by the heat treatment, the number density of SiO₄ as donors formed through bonding between interstitial oxygen atoms and silicon atoms as described above in the silicon crystal lattice becomes higher than the number density of boron atoms as acceptors in the silicon crystal lattice.

Returning to FIG. 2, the specific resistance value of the focus ring 25 that has been subjected to the heat treatment as described above is measured (step S25), and it is determined whether or not the measured specific resistance value is not more than a target value of the specific resistance value (step S26).

If the measured specific resistance value is still greater than the target value of the specific resistance value, then it is judged that the formation of SiO₄ has not yet leveled off and hence that the number of free electrons supplied into the focus ring 25 is still too low, in which case step S24 is returned to and the focus ring 25 is subjected to the heat treatment again. Once the measured specific resistance value is not more than the target value of the specific resistance value (“YES” in step S26), the present process is brought to an end. The focus ring 25 manufactured through the present process is then used in the chamber 11 of the substrate processing apparatus 10.

According to the substrate processing apparatus of the present embodiment described above, a focus ring 25 having p-type silicon as a parent material thereof is subjected to heat treatment at least once. Upon the focus ring 25 having p-type silicon as a parent material thereof being subjected to the heat treatment, formation of SiO₄ from oxygen atoms present as an impurity and silicon atoms is promoted, whereby free electrons are supplied into the focus ring 25, and hence the number of free electrons becomes greater than the number of positive holes in the focus ring 25, and thus the p-type silicon is inverted into apparently n-type silicon; after that, the formation of SiO₄ levels off, and hence supply of free electrons into the focus ring 25 stops. As a result, during subsequent repeated RIE, there is no inversion of the p-type silicon into apparently n-type silicon (that is, the focus ring is kept apparently n-type silicon), and the specific resistance value of the focus ring 25 does not change. A plurality of wafers W can thus be subjected to stable RIE reliably. Moreover, the high-frequency electric field around the wafer W is stable, and hence burning of a protective film on the wafer W (PR-burn) due to electrical discharge occurring between the wafer W and the focus ring 25 can be prevented from occurring.

Moreover, according to the substrate processing apparatus of the present embodiment described above, specific regions arise in the focus ring 25 after the predetermined heat treatment time T₂ has elapsed where the density of interstitial oxygen atoms is lower than the overall density of oxygen atoms including both oxygen atoms bonded to silicon atoms and interstitial oxygen atoms not bonded to silicon atoms in the silicon crystal lattice. Such a case that the density of interstitial oxygen atoms in specific regions of the silicon crystal lattice is lower than the overall density of oxygen atoms corresponds to some of the interstitial oxygen atoms in the specific regions being bonded to silicon atoms. Due to oxygen atoms being bonded to silicon atoms, donors that supply free electrons are formed, and hence the number of free electrons in the focus ring 25 after the heat treatment can be made to exceed the number of positive holes reliably. The specific resistance value of the focus ring 25 can thus be made stable, and hence a plurality of wafers W can be subjected to yet more stable RIE.

Moreover, in the focus ring 25 after the predetermined heat treatment time T₂ has elapsed, the number density of SiO₄ as donors formed through bonding between oxygen atoms and silicon atoms at least some interstitial sites in the silicon crystal lattice is greater than the number density of boron atoms as acceptors in the silicon crystal lattice. Each boron atom as an acceptor produces one positive hole, and hence if the number density of SiO₄ as donors is higher than the number density of boron atoms in the silicon crystal lattice, then the number of free electrons in the focus ring 25 after the heat treatment can be made to exceed the number of positive holes reliably. In particular, oxygen atoms that bond to silicon atoms in the formation of the SiO₄ act as bivalent donors, and hence if the number density of these oxygen atoms is not less than one half of the number density of boron atoms, then the number of free electrons in the focus ring 25 after the heat treatment can be made to exceed the number of positive holes reliably. As a result, the specific resistance value of the focus ring 25 can be made stable, and hence a plurality of wafers W can be subjected to yet more stable RIE.

In the substrate processing apparatus according to the present embodiment described above, the focus ring 25 is subjected to heat treatment. However, other component elements having p-type silicon as a parent material thereof that form electrical circuitry in the chamber 11, for example the electrode plate 36 of the shower head 32, may similarly be subjected to such heat treatment. If an electrode plate 36 having p-type silicon as a parent material thereof is subjected to such heat treatment, then as for the focus ring 25 as described above, the p-type silicon is inverted into apparently n-type silicon, and then after that, the formation of SiO₄ levels off, and hence supply of free electrons into the electrode plate 36 stops. As a result, during subsequent repeated RIE, the specific resistance value of the electrode plate 36 does not change, and hence the high-frequency electric field above a wafer W being processed can be made stable. A plurality of wafers W can thus be subjected to stable RIE reliably.

Moreover, in the substrate processing apparatus according to the present embodiment described above, the specific resistance value of the focus ring 25 that is made of p-type silicon to which a predetermined amount of boron has been added and has been subjected to heat treatment (i.e. the specific resistance value after the predetermined heat treatment time T₂ has elapsed) is lower than the specific resistance value of the p-type silicon to which the predetermined amount of boron has been added but heat treatment has not been carried out (the specific resistance value at the heat treatment commencement time T₀). For the focus ring 25, formation of SiO₄ is promoted by the heat treatment, and then levels off, the number of free electrons in the focus ring 25 becomes greater than the number of positive holes, and the p-type silicon is inverted into apparently n-type silicon. As a result, during subsequent repeated RIE, change of the specific resistance value of the focus ring 25 can be suppressed, and hence a plurality of wafers W can be subjected to yet more stable RIE.

In the embodiment described above, description is given for the case that the substrate processing apparatus is an etching apparatus. However, substrate processing apparatuses to which the present invention can be applied are not limited thereto, but rather the present invention may also be applied to other apparatuses that carry out processing using a plasma, for example a CVD (chemical vapor deposition) apparatus or a PVD (physical vapor deposition) apparatus.

Furthermore, in the embodiment described above, the substrates processed are semiconductor wafers. However, the substrates processed are not limited thereto, but rather may also be, for example, LCD (liquid crystal display) or FPD (flat panel display) glass substrates.

It is to be understood that the object of the present invention can also be attained by supplying to a system or apparatus a storage medium storing program code of software that realizes the functions of an embodiment as described above, and then causing a computer (or CPU, MPU, etc.) of the system or apparatus to read out and execute the program code stored in the storage medium.

In this case, the program code itself read out from the storage medium realizes the functions of the embodiment, and hence the program code and the storage medium storing the program code constitute the present invention.

The storage medium for supplying the program code may be, for example, a floppy (registered trademark) disk, a hard disk, a magnetic-optical disk, an optical disk such as a CD-ROM, a CD-R, a CD-RW, a DVD-ROM, a DVD-RAM, a DVD-RW, or a DVD+RW, a magnetic tape, a nonvolatile memory card, or a ROM. Alternatively, the program code may be downloaded via a network.

Moreover, it is to be understood that the functions of the embodiment can be realized not only by executing program code read out by the computer, but also by causing an OS (operating system) or the like operating on the computer to carry out part or all of the actual processing based on instructions of the program code.

Furthermore, it is to be understood that the functions of the embodiment can also be realized by writing the program code read out from the storage medium into a memory provided on an expansion board inserted into the computer or in an expansion unit connected to the computer, and then causing a CPU or the like provided on the expansion board or in the expansion unit to carry out part or all of the actual processing based on instructions of the program code.

The form of the program code may be, for example, object code, program code executed by an interpreter, or script data supplied to an OS.

What is claimed is:

1. A substrate processing apparatus comprising:
a processing chamber in which a substrate is housed and subjected to plasma processing; and
a component element having p-type silicon as a parent material thereof, at least part of said component element being exposed to an interior of said processing chamber;
wherein said component element has been subjected to heat treatment at least once.

2. A substrate processing apparatus as claimed in claim 1, wherein said component element has regions therein where a density of interstitial oxygen atoms is lower than an overall density of oxygen atoms in a silicon crystal lattice.

3. A substrate processing apparatus as claimed in claim 1, wherein the p-type silicon is formed by adding a group 13 element to silicon, and in said component element, a number density of donors formed through bonding between interstitial atoms and silicon atoms in a silicon crystal lattice of said component element is higher than a number density of acceptors comprising the group 13 element in the silicon crystal lattice.

4. A substrate processing apparatus as claimed in claim 3, wherein the interstitial atoms are oxygen atoms, and the number density of the oxygen atoms bonded to silicon atoms is not less than one half of the number density of the acceptors comprising the group 13 element.

5. A substrate processing apparatus as claimed in claim 1, wherein said component element is a focus ring provided surrounding the substrate housed in said processing chamber.

6. A substrate processing apparatus as claimed in claim 1, wherein said component element is an upper electrode disposed in an upper portion of said processing chamber.

7. A substrate processing apparatus comprising:
a processing chamber in which a substrate is housed and subjected to plasma processing; and
a component element having p-type silicon as a parent material thereof, at least part of said component element being exposed to an interior of said processing chamber;
wherein a predetermined amount of a group 13 element is added to the p-type silicon, and wherein a specific resistance value of said component element is lower than a specific resistance value of the p-type silicon to which the predetermined amount of the group 13 element has been added.

8. A substrate processing method of subjecting a substrate to plasma processing, the method comprising:
a housing step of housing a substrate in a processing chamber in which is disposed a component element that has p-type silicon as a parent material thereof and has been subjected to heat treatment at least once; and
a plasma processing step of subjecting the substrate to plasma processing with a plasma produced in the processing chamber.

9. A computer-readable storage medium storing a program for causing a computer to implement a substrate processing method of subjecting a substrate to plasma processing, the program comprising:
a housing module for housing a substrate in a processing chamber in which is disposed a component element that has p-type silicon as a parent material thereof and has been subjected to heat treatment at least once; and
a plasma processing module for subjecting the substrate to plasma processing with a plasma produced in the processing chamber.
